(19) United States
(12) Patent Application Publication
(10) Pub. No.: US 2023/0071650 A1
(43) Pub. Date: Mar. 9, 2023

(54) OLED DISPLAY PANEL AND METHOD FOR MANUFACTURING SAME, AND DISPLAY DEVICE

(71) Applicants: CHENGDU BOE OPTOELECTRONICS TECHNOLOGY CO., LTD., Sichuan (CN); BOE TECHNOLOGY GROUP CP., LTD., Beijing (CN)

(72) Inventors: Bo Shi, Beijing (CN); Chi Yu, Beijing (CN); Weiyun Huang, Beijing (CN); Rui Zhou, Beijing (CN)

(21) Appl. No.: 17/798,952

(22) PCT Filed: Oct. 12, 2021
(86) PCT No.: PCT/CN2021/123308

§ 371 Date: Oct. 27, 2022

(30) Foreign Application Priority Data
Nov. 26, 2020 (CN) 202011348805.7

(51) Int. Cl. H01L 51/52; H01L 51/56

(52) U.S. Cl. CPC H01L 51/5268; H01L 51/5293; H01L 51/56; H01L 51/5237

(57) ABSTRACT

Provided is an OLED display panel. The OLED display panel includes an OLED display substrate; a package substrate, opposite to the OLED display substrate, wherein a gap is defined between the package substrate and the OLED display substrate, and the gap is filled with a gas having a refractive index less than that of the package substrate; and a scattering structure, disposed on a side, distal from the OLED display substrate, of the package substrate, wherein the scattering structure is a single-layer or multi-layer structure configured to scatter light passing through the scattering structure.

### CROSS-REFERENCE TO RELATED APPLICATION

This application is a 371 of PCT application No. PCT/CN2021/123308, filed on Oct. 12, 2021, which claims priority to Chinese Patent Application No. 202011348805.7, filed on Nov. 26, 2020 and entitled “OLED DISPLAY PANEL AND MANUFACTURING METHOD THEREFOR, AND DISPLAY DEVICE,” the entire contents of which are incorporated herein by reference.

### TECHNICAL FIELD

The present disclosure relates to the field of displays, and in particular, relates to an OLED display panel and method for manufacturing same, and display device.

### BACKGROUND

Organic light-emitting diode (OLED) display panels have a small size and good performance, and are being widely used in more and more electrical devices. An OLED display^{,} panel includes an OLED display substrate and a package substrate. A gap is defined between the OLED display substrate and the package substrate. and the gap is filled with gas (referred to as a gas layer).

### SUMMARY

Embodiments of the present disclosure provide an OLED display panel and a method for manufacturing the same, and a display device. The technical solutions are as follows:

According to one aspect of the embodiments of the present disclosure, an OLED display panel is provided. The OLED display panel includes:

an OLED display substrate;

a package substrate, opposite to the OLED display substrate, wherein a gap is defined between the package substrate and the OLED display substrate, and the gap is filled with gas having a refractive index less than that of the package substrate;

a scattering structure, disposed on a side, distal from the OLED display substrate, of the package substrate, wherein the scattering structure is a single-layer or multi-layer structure configured to scatter light passing through the scattering structure.

In one embodiment of the present disclosure, the scattering structure is a polarizer with at least one rough surface, wherein the polarizer is disposed on a side, distal from the OLED display substrate, of the package substrate.

In one embodiment of the present disclosure, the scattering structure includes an anti-glare (AG) film and a polarizer which are sequentially laminated on the package substrate along a direction away from the package substrate.

In one embodiment of the present disclosure, the scattering structure includes a scattering film and a polarizer; wherein

the scattering film and the polarizer are sequentially laminated on the package substrate along a direction away from the package substrate; or

the polarizer and the scattering film are sequentially laminated on the package substrate along a direction away from the package substrate.

In one embodiment of the present disclosure, the scattering film includes an internal refractive-index distribution structure configured to control a transmission direction and/or a scattering direction of light.

In one embodiment of the present disclosure, the scattering structure includes a polarizer, an adhesive layer, and a cover glass (CG); wherein the adhesive layer includes atomized particles; and the polarizer, the adhesive layer, and the CG are sequentially laminated on the package substrate along a direction away from the package substrate.

In one embodiment of the present disclosure, the atomized particles include acrylic particles.

In one embodiment of the present disclosure, the scattering structure includes a polarizer and a transparent insulating layer with an embossing structure configured to change a transmission direction and/or a scattering direction of light; wherein the transparent insulating layer and the polarizer are sequentially laminated on the package substrate along a direction away from the package substrate, and the embossing structure is disposed on a side, facing towards the polarizer, of the transparent insulating layer.

In one embodiment of the present disclosure, the transparent insulating layer is an acrylic layer or a polyimide layer.

In one embodiment of the present disclosure, a haze of a layer on which the scattering structure is disposed is between 10% and 90%.

In one embodiment of the present disclosure, the gas is nitrogen or an inert gas.

In one embodiment of the present disclosure, a base substrate of the OLED display substrate is a rigid substrate, and the package substrate is a rigid substrate.

According to another aspect of the embodiments of the present disclosure, a method for manufacturing an OLED display panel is provided. The method includes:

providing an OLED display substrate;

packaging the OLED display substrate by using a package substrate, wherein a gap is defined between the package substrate and the OLED display substrate, and the gap is filled with gas having a refractive index less than that of the package substrate;

forming a scattering structure on the package substrate, wherein the scattering structure is a single-layer or multi-layer structure configured to scatter light passing through the scattering structure.

In one embodiment of the present disclosure, forming the scattering structure on the package substrate includes:

surface treating the polarizer such that at least one surface of the polarizer is a rough surface;

attaching the polarizer to a side, distal from the OLED display substrate, of the package substrate.

In one embodiment of the present disclosure, forming the scattering structure on the package substrate includes:

sequentially forming an AG film and a polarizer on the package substrate.

In one embodiment of the present disclosure, forming the scattering structure on the package substrate includes:

sequentially forming a scattering film and a polarizer on the package substrate; or

sequentially forming a polarizer and a scattering film on the package substrate.

In one embodiment of the present disclosure, forming the scattering structure on the package substrate includes:

forming a polarizer on the package substrate; and

bonding the polarizer and a CG by an adhesive layer including atomized particles.

In one embodiment of the present disclosure, forming the scattering structure on the package substrate includes:

forming a transparent insulating layer on the package substrate;

patterning the transparent insulating layer such that an embossing structure configured to change a transmission direction and/or a scattering direction of light is formed on the side, distal from the package substrate, of the transparent insulating layer; and

forming a polarizer on a side, distal from the package substrate, of the transparent insulating layer.

According to another aspect of the embodiments of the present disclosure, a display device is provided, the display device includes the OLED display panel according to in the first aspect.

### BRIEF DESCRIPTION OF THE DRAWINGS

For clearer descriptions of the technical solutions in the embodiments of the present disclosure, the following briefly describes the accompanying drawings required for describing the embodiments. Apparently, the accompanying drawings in the following description illustrate merely some embodiments of the present disclosure, and those of ordinary skill in the art may still derive other drawings from these accompanying drawings without creative efforts.

FIG. 1 is a cross-sectional view of an OLED display panel according to an embodiment of the present disclosure;

FIG. 2 is a cross-sectional view of a polarizer according to an embodiment of the present disclosure;

FIG. 3 is a cross-sectional view of another OLED display panel according to an embodiment of the present disclosure;

FIG. 4 is a cross-sectional view of another OLED display panel according to an embodiment of the present disclosure;

FIG. 5 is a schematic diagram of an internal structure of a scattering film according to an embodiment of the present disclosure;

FIG. 6 is a schematic diagram of an internal structure of another scattering film according to an embodiment of the present disclosure;

FIG. 7 is a cross-sectional view of another OLED display panel according to an embodiment of the present disclosure;

FIG. 8 is a cross-sectional view of another OLED display panel according to an embodiment of the present disclosure;

FIG. 9 is a schematic structural diagram of a Half Tone Mask according to an embodiment of the present disclosure;

FIG. 10 is a flowchart of a process for manufacturing an OLED display panel according to an embodiment of the present disclosure;

FIG. 11 is a process diagram for manufacturing a scattering structure according to an embodiment of the present disclosure; and

FIG. 12 is a process diagram for manufacturing a scattering structure according to an embodiment of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

In the related art, when monochromatic light illuminates the package substrate of an OLED display panel, one part of the light may be reflected on a surface of the package substrate, and the other part of the light may enter the package substrate and the gas layer, and may be reflected by^{,} the OLED display substrate and exit out of the package substrate. Since an optical path difference is present between these two parts of light, interference may be caused, interference stripes that are bright-dark alternating may appear on the OLED display panel. Since natural light is polychromatic light, when natural light enters the package substrate and the gas layer, light of different wavelengths (i.e., colors) may be dispersive in the package substrate and the gas layer due to different refractive indexes, which may be reflected by the OLED display panel and then exit out of the package substrate at different angles with different light ranges, and may respectively interface with the reflected light on the different position of the surface of the package substrate. As a result, rainbow stripes appear on a surface of the OLED display panel, and a display effect is affected.

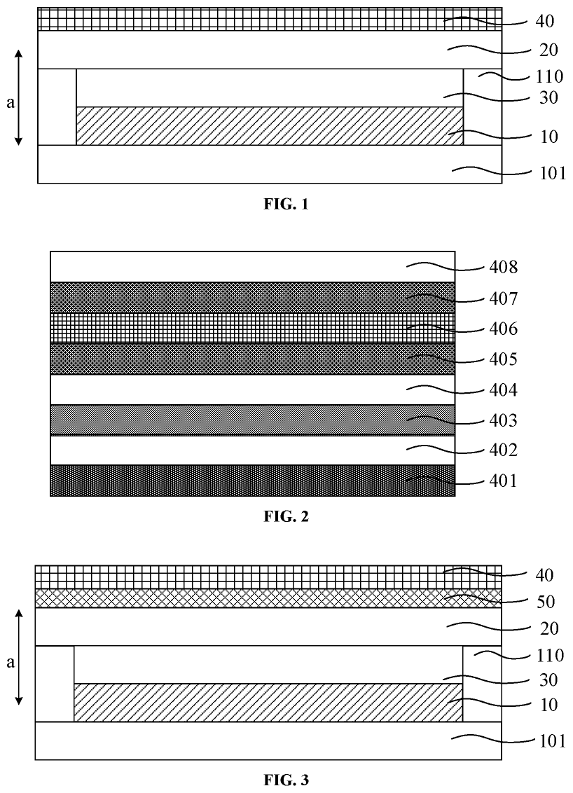

FIG. 1 is a cross-sectional view of an OLED display panel according to an embodiment of the present disclosure. Referring to FIG. 1, an OLED display substrate 10, a package substrate 20, and a scattering structure are included. The package substrate 20 is opposite to the OLED display substrate 10, and a gap 30 is defined between the package substrate 20 and the OLED display substrate 10. The gap 30 is filled with gas having a refractive index less than that of the package substrate 20. The scattering structure is disposed on a side, distal from the OLED display substrate 10, of the package substrate 20, and the scattering structure is a single-layer or multi-layer structure configured to scatter light passing through the scattering structure.

As mentioned above, since the refractive index of the gas is less than that of the package substrate, the light after passing through the package substrate and the gas may produce an optical path difference with the light reflected by the package substrate, such that light may interfere in the subsequent propagation process and rainbow stripes may appear on the surface of the OLED display panel. In the embodiments of the disclosure, the scattering structure is arranged on the package substrate, and the light is scattered by the scattering structure after passing through the scattering structure, such that the coherence of the light is reduced or even disappears, and the interference of the light is suppressed, thereby ameliorating the rainbow stripes on the surface of the OLED display panel.

The interference that occurs when light passes through a medium with the same thickness is an equal inclination interference. In the embodiments of the present disclosure, the thickness of the gap 30 is same in a direction perpendicular to the surface of the OLED display substrate 10, that is, the interference that occurs in the embodiments of the present disclosure is an equal inclination interference as well.

In the embodiments of the present disclosure, the OLED display panel substrate 10 has a cathode layer, and the cathode layer has a smooth surface. The light entering the gap 30 is reflected by the smooth surface of the cathode layer of the OLED display panel substrate 10.

Exemplarily, the cathode layer is a metal layer, such as an aluminum layer or a magnesium layer.

In one embodiment of the present disclosure, the scattering structure is a polarizer (POL) 40. The polarizer 40 is disposed on a side, distal from the OLED display substrate 10, of the package substrate 20. The at least one surface of the polarizer 40 is a rough surface.

In embodiments of the present disclosure, a polarizer with a rough surface is obtained by surface treating the surface of the polarizer. The surface treatment is performed on the surface of the polarizer 40 to form a rough surface on at least one surface of the polarizer 40. When light illuminates the polarizer 40 for the first time, the light is scattered by the rough surface of the polarizer 40 at this time due to the rough surface of the surface of the polarizer 40. The scattered light illuminates to the package substrate 20. One part of the light is reflected by the package substrate 20, and the light reflected by the package substrate 20 passes through the polarizer 40 for the second time and is scattered by the rough surface of the polarizer 40 for the second time. The other part of the light enters the gap 30, and the light entering the gap 30 is reflected by the OLED display substrate 10, and this part of the light passes through the polarizer 40 for the second time and is scattered by the rough surface of the polarizer 40 again. Upon scattering of the light, the coherence of the light is reduced, and the interference generated by the light is suppressed, thereby ameliorating the rainbow stripes on the surface of the OLED display panel.

At the same time, surface treatment is performed directly on the surface of the polarizer 40 such that the polarizer 40 has a scattering structure. In this way, the need to arrange other structures in the OLED display panel to form the scattering structure is eliminated, and the thickness of the OLED display panel is not increased.

In the embodiments of the present disclosure, surface treatment may be performed on both opposite surfaces of the polarizer 40 such that both opposite surfaces of the polarizer 40 are rough surfaces. Alternatively, surface treatment may be performed on one of the surfaces of the polarizer 40 such that one of the surfaces of the polarizer 40 is a rough surface.

In the embodiments of the present disclosure, when one of the surfaces of the polarizer 40 is a rough surface, the rough surface faces towards a side distal from the OLED display substrate.

In the embodiments of the present disclosure, when the scattering structure includes the polarizer 40, the scattering structure is a single-layer structure.

FIG. 2 is a cross-sectional view of a polarizer according to the embodiments of the present disclosure. Referring to FIG. 2, the polarizer 40 includes a release film 401, a first adhesion layer 402, a retardation film 403, a second adhesion layer 404, a first triacetyl cellulose (TAC) film 405, a polyvinyl alcohol (PVA) layer 406, a second triacetyl cellulose film 407, and a protective film 408.

The release film 401 has an adhesive property to attach the polarizer 40 to the package substrate 20, thereby facilitating manufacturing. The first adhesion layer 402 and the second adhesion layer 404 adhere the retardation film 403 to the first triacetyl cellulose film 405, the polyvinyl alcohol layer 406, and the second triacetyl cellulose film 407. In the polarizer 40, the polyvinyl alcohol layer 406 plays a part in polarization, but the polyvinyl alcohol layer 406 is easily hydrolyzed. For polarization of the polyvinyl alcohol layer 406, a layer of triacetyl cellulose film (i.e., the first triacetyl cellulose film 405 and the second triacetyl cellulose film 407) is attached to each of the two opposite sides of the polyvinyl alcohol layer 406 to protect the polyvinyl alcohol layer 406. At the same time, the protective film 408 and the retardation film 403 with a phase difference compensation value may be arranged in the polarizer 40 according to the requirements of the product.

In the embodiments of the present disclosure, the second triacetyl cellulose film 407 of the polarizer 40 may be surface treated, or both the first triacetyl cellulose film 405 and the second triacetyl cellulose film 407 of the polarizer 40 may be surface treated.

FIG. 3 is a cross-sectional view of another OLED display panel according to an embodiment of the present disclosure. Referring to FIG. 3, the scattering structure includes an anti-glare (AG) film 50 and a polarizer 40 which are sequentially laminated on the package substrate 20 along the a-direction away from the package substrate 20.

In the embodiments of the disclosure, the AG film 50 is a surface treatment film. When the light illuminates the AG film 50 for the first time, the AG film 50 may scatter the light, the scattered light illuminates the package substrate 20. In this case, one part of the light is reflected by the package substrate 20, and the light reflected by the package substrate 20 passes through the AG film 50 for the second time and is scattered by the AG film 50 for the second time; and the other part of the light enters the gap 30, and the light entering the gap 30 is reflected by the OLED display substrate 10. Then, this part of the light passes through the AG film 50 for the second time and is scattered by the AG film 50 again. Upon scattering of the light, the coherence of the light is reduced, and the interference generated by the light may be suppressed, thereby ameliorating the rainbow stripes on the surface of the OLED display panel.

At the same time, the AG film 50 may reduce the interference of ambient light to the OLED display panel and the surface reflection of the OLED display panel, thereby improving the display effect.

In the embodiments of the present disclosure, the AG film 50 is adhesive, the AG film 50 may be directly attached to the package substrate 20, and then the polarizer 40 may be attached to the AG film 50, which is convenient for manufacturing.

In the embodiments of the present disclosure, when the scattering structure includes the AG film 50 and the polarizer 40, the scattering structure is a multi-layer structure.

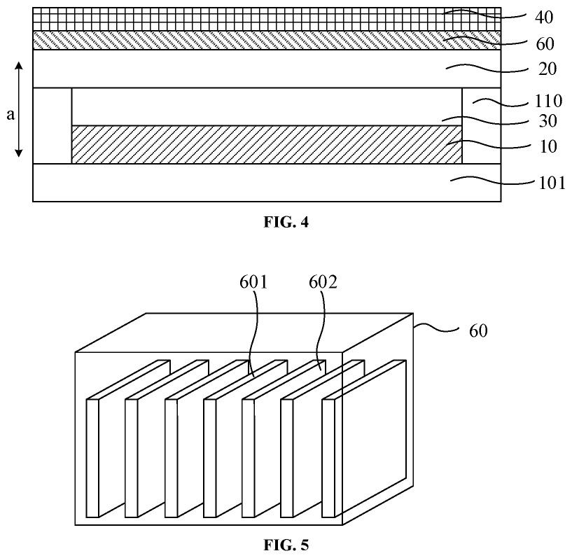

FIG. 4 is a cross-sectional view of another OLED display panel according to an embodiment of the present disclosure. Referring to FIG. 4, the scattering structure includes a scattering film 60 and a polarizer 40. The scattering film 60 and the polarizer 40 are sequentially laminated on the package substrate along the a-direction away from the package substrate.

In the embodiments of the present disclosure, when the light illuminates the scattering film 60 for the first time, the scattering film 60 may scatter the light, and the scattered light illuminates the package substrate 20. One part of the light is reflected by the package substrate 20, and the light reflected by the package substrate 20 passes through the scattering film 60 for the second time and is scattered by the scattering film 60 for the second time. The other part of the light enters the gap 30, and the light entering the gap 30 is reflected by the OLED display substrate 10, then this part of the light passes through the scattering film 60 for the second time and is scattered by the scattering film 60 again. Upon scattering of the light, the coherence of the light is reduced, and the interference generated by the light may be suppressed, thereby ameliorating the rainbow stripes on the surface of the OLED display panel.

In the embodiments of the present disclosure, the scattering film 60 includes an internal refractive-index distribution structure configured to control the transmission direction and/or the scattering direction of light. This structure may change the transmission direction and/or the scattering direction of the light passing through the scattering film 60, that is, the light passing through the scattering film 60 is scattered such that the coherence of the light is reduced, and the interference generated between the scattered light and the light reflected by the OLED display substrate 10 is suppressed, thereby ameliorating the rainbow stripes on the surface of the OLED display panel.

In the embodiments of the present disclosure, the scattering film 60 may be an anisotropic light diffusion film, which may be referred to as an Internal Refractive-index Distribution Film (IDF).

In the embodiments of the present disclosure, the scattering film 60 is adhesive. The scattering film 60 may be directly attached to the package substrate 20, and then the polarizer 40 may be attached to the scattering film 60, which is convenient for manufacturing.

In FIG. 4, the scattering film 60 and the polarizer 40 are sequentially laminated on the package substrate 20 along the a-direction away from the package substrate 20, that is, the polarizer 40 is disposed on the scattering film 60. In other embodiments, the polarizer 40 and the scattering film 60 may be sequentially laminated on the package substrate 20 along the a-direction away from the package substrate 20, that is, the scattering film 60 is disposed on the polarizer 40.

In the embodiments of the present disclosure, when the scattering structure includes the scattering film 60 and the polarizer 40, the scattering structure is a multi-layer structure.

FIG. 5 is a schematic diagram of an internal structure of a scattering film according to an embodiment of the present disclosure. Referring to FIG. 5, the internal refractive-index distribution structure in the scattering film 60 includes a plurality of plate-like structures 601 arranged in parallel at intervals. The plate surface of the plate-like structures 601 is perpendicular to the surface of the scattering film 60, and the portion 602 between the plate-like structures 601 has a refractive index different from that of the plate-like structures 601. When light passes through the scattering film 60 at a certain angle, the light may be refracted at the interface of the portion 602 between the plate-like structures 601, which changes the direction of the light, and thereby achieves scattering of the light.

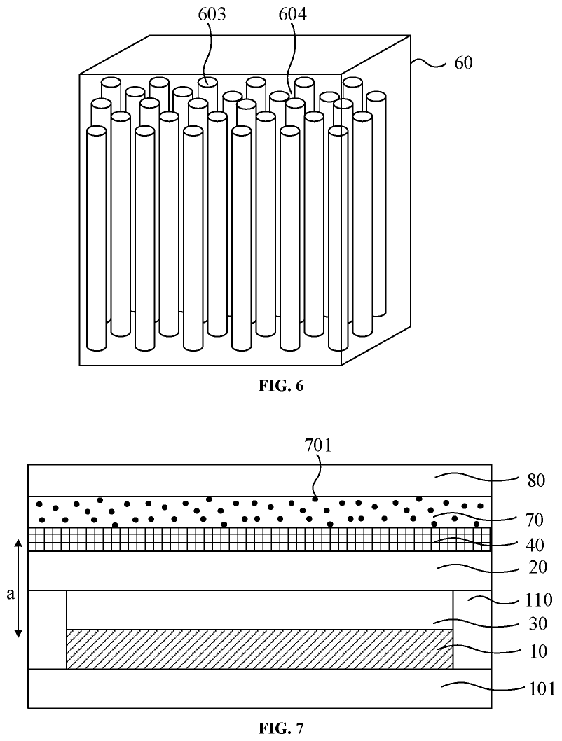

FIG. 6 is a schematic diagram of an internal structure of another scattering film according to an embodiment of the present disclosure. The difference between FIG. 6 and FIG. 5 lies in the different shape of the internal refractive-index distribution structure, and the internal refractive-index distribution structure in FIG. 6 includes a plurality of columnar structures 603 arranged in parallel at intervals. The axis of the columnar structures 603 is perpendicular to the surface of the scattering film 60, and the portion 604 between the columnar structures 603 has a refractive index different from that of the columnar structures 603. When the light passes through the scattering film 60 at a certain angle, the light may be refracted at the interface of the portion 604 between the columnar structures 603, which changes the direction of the light, and thereby achieves scattering of the light.

In the embodiments of the present disclosure, the scattering effect of the scattering film 60 on light may be altered by changing the refractive indexes of the plate-like structure 601 and the columnar structure 603, as well as the tilt angles of the plate-like structure 601 and the columnar structure 603.

The tilt angle is the angle between the plate surface of the plate-like structure 601 or the axis of the columnar structure 603 and the surface of the scattering film 60.

In the embodiments of the present disclosure, when the thickness of the plate-like structure 601 in FIG. 5 is equal to the thickness of the scattering film 60, the portion 602 between the plate-like structures 601 also appears as a plate-like structure, and in this case the internal refractive-index distribution structure may be referred to as a shutter structure.

FIG. 7 is a cross-sectional view of another OLED display panel according to an embodiment of the present disclosure. Referring to FIG. 7, the scattering structure includes a polarizer 40, an adhesive layer 70, and a cover glass (CG) 80. The adhesive layer 70 includes atomized particles 701. The polarizer 40, the adhesive layer 70, and the CG 80 are sequentially laminated on the package substrate 20 along the a-direction away from the package substrate 20.

In the embodiments of the present disclosure, the atomized particles 701 may scatter the light. When the light passes through the adhesive layer 70, the atomized particles 701 within the adhesive layer 70 scatter the light. The scattered light illuminates to the package substrate 20. One part of the light is reflected by the package substrate 20, and the light reflected by the package substrate 20 passes through the adhesive layer 70 for the second time and is scattered by the atomized particles 701 for the second time. The other part of the light enters the gap 30, and the light entering the gap 30 is reflected by the OLED display substrate 10, and this part of the light passes through the adhesive layer 70 for the second time and is scattered by atomized particles 701 again. Upon scattering of the light, the coherence of the light is reduced, and the interference generated by the light is suppressed, thereby ameliorating the rainbow stripes on the surface of the OLED display panel.

In the embodiments of the present disclosure, the adhesive layer 70 is a film layer originally present in the OLED display panel. The scattering structure is formed by adding the atomized particles 701 to the adhesive layer 70, which does not increase the thickness of the adhesive layer 70. The atomized particles 701 are uniformly dispersed in the adhesive layer 70.

In the embodiments of the present disclosure, the atomized particles 701 include acrylic particles. Acrylic is easily available and low cost, which reduces the cost of manufacturing OLEDs.

In the embodiments of the present disclosure, the adhesive layer 70 may be a solid optical clear adhesive, such as an optical clear resin (OCR) adhesive layer or an optically clear adhesive (OCA) layer.

In the embodiments of the present disclosure, when the scattering structure includes the polarizer 40, the adhesive layer 70 and the CG 80, the scattering structure is a multi-layer structure.

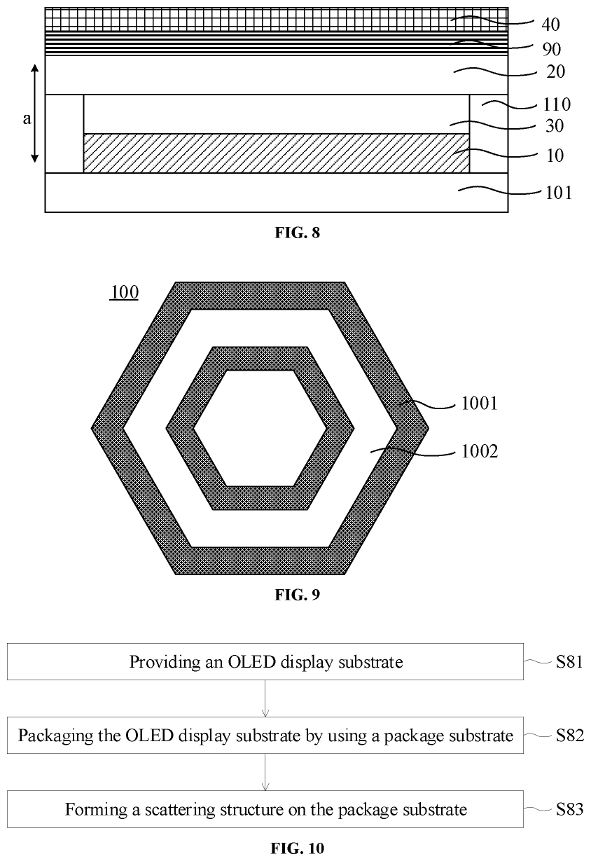

FIG. 8 is a cross-sectional view of another OLED display panel according to an embodiment of the present disclosure. Referring to FIG. 8, the scattering structure includes a transparent insulating layer 90 with an embossing structure configured to change a transmission direction and/or a scattering direction of light and a polarizer 40. The transparent insulating layer 90 and the polarizer 40 are sequentially laminated on the package substrate 20 along the a-direction away from the package substrate 20, and the embossing structure is disposed on a side, facing towards the polarizer 40, of the transparent insulating layer 90.

The embossing structure may change the transmission direction and/or the scattering direction of light. When the light illuminates the transparent insulating layer 90 for the first time, the embossing structure may change the transmission direction and/or the scattering direction of light, that is, may scatter the light. The scattered light illuminates the package substrate 2. One part of the light is reflected by the package substrate 20, and the light reflected by the package substrate 20 passes through the transparent insulating layer 90 for the second time and is scattered by the embossing structure for the second time. The other part of the light enters the gap 30, the light entering the gap 30 is reflected by the OLED display substrate 10, and then this part of the light passes through the transparent insulating layer 90 for the second time and is scattered by the embossing structure again. Upon scattering of the light, the coherence of the light is reduced, and the interference generated by the light may be suppressed, thereby ameliorating the rainbow stripes on the surface of the OLED display panel.

In the embodiments of the present disclosure, the embossing structure is composed of bump structures that are spaced apart on the surface of the transparent insulating layer 90.

In embodiments of the present disclosure, the transparent insulating layer 90 is an acrylic layer or a polyimide (PI) layer.

In embodiments of the present disclosure, the transparent insulating layer 90 may be patterned by a half tone mask (HTM) such that the side, facing towards the polarizer 40, of the transparent insulating layer 90 has a bump structure.

In the embodiments of the present disclosure, during the patterning process, different shaped embossing structures may be obtained by controlling the exposure speed and changing the pattern shapes of the HTM.

FIG. 9 is a schematic structural diagram of a HTM according to an embodiment of the present disclosure. Referring to FIG. 9, the boundary of the local structure of the HTM is hexagonal. The HTM 100 includes a mask portion 1001 and an exposure portion 1002. During the patterning process, the thicknesses etched in the transparent insulating layer 90 corresponding to the mask portion 1001 and the exposure portion 1002 are different. The transparent insulating layer 90 has an embossing structure on the side towards the polarizer 40.

FIG. 9 only shows one pattern of the HTM. However, the actual halftone mask panel is a combination of multiple patterns.

In other embodiments, the local structure of the HTM may be in other shapes, such as a quadrilateral or a pentagon, as long as it is possible to form an embossing structure on the surface of the transparent insulating layer 90.

In the embodiments of the present disclosure, when the scattering structure includes transparent insulating layer 90 and the polarizer 40, the scattering structure is a multi-layer structure.

In one embodiment of the present disclosure, a haze of a layer in which the scattering structure is disposed is between 10% and 90%.

For example, when the scattering structure is a polarizer 40, the haze of the polarizer 40 is between 10% and 90%. When the scattering structure includes the AG film 50 and the polarizer 40, the AG film 50 has a haze of between 10% and 90%. When the scattering structure includes the scattering film 60 and the polarizer 40, the haze of the scattering film 60 is between 10% and 90%. When the scattering structure includes the polarizer 40, the adhesive layer 70 and the CG 80, the haze of the adhesive layer 70 is between 10% and 90%. When the scattering structure includes the transparent insulating layer 90 and the polarizer 40, the haze of the transparent insulating layer 90 is between 10% and 90%.

In the embodiments of the present disclosure, when the haze of the layer in which the scattering structure is disposed is between 10% and 90%, the rainbow stripes on the surface of the OLED display panel may be ameliorated.

Exemplarily, the haze of the layer in which the scattering structure is disposed is between 40% and 50%. When the haze of the layer in which the scattering structure is disposed is between 40% and 50%, an amelioration of the rainbow stripes on the surface of the OLED display panel is most effective, which does not affect the display of the OLED display panel.

In one embodiment of the present disclosure, the gas is nitrogen (N₂) or an inert gas.

Exemplarily, the inert gas may be argon.

In an embodiment of the present disclosure, the OLED display panel is packaged under nitrogen or an inert gas such that the gap 30 is filled with nitrogen or an inert gas.

Exemplarily, the gas is nitrogen, and the refractive index of the nitrogen is 1.0.

In the embodiments of the present disclosure, the gap 30 is filled with the nitrogen or the inert gas, and the nitrogen or the inert gas may prevent outside oxygen and moisture from entering the OLED display panel.

In the embodiments of the present disclosure, the package substrate 20 is a rigid substrate, for example, the package substrate 20 is a glass substrate with a refractive index of 1.53, that is, the refractive index of the gas is less than the refractive index of the package substrate 20.

In the embodiments of the present disclosure, the polarizers 40 shown in FIG. 3, FIG. 4, FIG. 7, and FIG. 8 are plain polarizers without additional surface treatments, that is, the roughness of the surface of each of these polarizers is lower than that of the rough surface of the polarizer shown in FIG. 1.

As shown in FIG. 1, FIG. 3, FIG. 4, FIG. 7, and FIG. 8, the package substrate 20 is bonded to the base substrate 101 of the OLED display substrate 10 via a frame sealant 110.

In one embodiment of the present disclosure, the substrate 101 of the OLED display substrate 10 is a rigid substrate to ensure the strength of the OLED display panel. Rigid substrate refers to the substrate being more rigid and less prone to bending.

Exemplarily, the OLED display substrate 10 may be a glass substrate.

In the embodiments of the present disclosure, some parts of the display region are provided with the scattering structure, while some parts of the partial display region are not provide with the scattering structure. Then, when observed by the naked eyes on the display surface, the display effect of the display region with the scattering structure is not different from that of the display region without the scattering structure. That is, the above scattering structure exerts no effect on the display effect of the display substrate 10.

FIG. 10 is a flowchart of a process for manufacturing an OLED display panel according to the embodiments of the present disclosure. Referring to FIG. 10, the method includes:

In step S81, an OLED display substrate is provided.

In one embodiment of the present disclosure, the base substrate of the OLED display substrate is a rigid substrate, such as glass substrate.

In step S82, the OLED display substrate is packaged by using a package substrate, and a gap is defined between the package substrate and the OLED display substrate, and the gap is filled with gas having a refractive index less than that of the package substrate.

In the embodiments of the present disclosure, the OLED display substrate may be packaged by using a glass substrate.

In the embodiments of the present disclosure, the OLED display panel may be packaged under an environment with nitrogen or an inert gas. In this case, the gap is filled with nitrogen or an inert gas.

Exemplarily, the gap is filled with nitrogen, which has a refractive index of 1.0. The package substrate is a glass substrate, which has a refractive index of 1.53, that is, the refractive index of the gas is less than that of the package substrate.

In step S83, a scattering structure is formed on the package substrate, wherein the scattering structure is a single-layer or multi-layer structure configured to scatter light passing through the scattering structure.

Since the refractive index of the gas is less than that of the package substrate, the light after passing through the package substrate and the gas may produce an optical path difference over the light reflected by the package substrate, such that light may interfere in the subsequent propagation process and rainbow stripes may appear on the surface of the OLED display panel. In the embodiments of the disclosure, a scattering structure is arranged on the package substrate, and the light is scattered by the scattering structure after passing through the scattering structure, such that the coherence of the light is reduced or even disappears, and the interference of the light is suppressed, thereby ameliorating the rainbow stripes on the surface of the OLED display panel.

In the embodiments of the present disclosure, more types of scattering structures are provided, and the methods of manufacturing different scattering structures are described below.

In one embodiment of the present disclosure, the scattering structure is a polarizer, and the surface of the polarizer distal from the package substrate is a rough surface.

Forming the scattering structure on the package substrate includes: surface treating the polarizer such that at least one surface of the polarizer is a rough surface; and

attaching the polarizer to a side, distal from the OLED display substrate, of the package substrate.

In the embodiments of the present disclosure, the second triacetyl cellulose film of the polarizer may be surface treated such that one of the surfaces of the polarizer is a rough surface.

Exemplarily, the rough surface faces towards the side distal from the OLED display substrate.

In another embodiment of the present disclosure, the scattering structure includes an AG film and a polarizer which are sequentially laminated on the package substrate 20 along the direction away from the package substrate.

Forming the scattering structure on the package substrate includes: sequentially forming the AG film and the polarizer on the package substrate.

In the embodiments of the present disclosure, the AG film and the polarizer are adhesive. The AG film may be directly attached to the package substrate 20, and then the polarizer 40 may be attached to the AG film 50.

In another embodiment of the present disclosure, the scattering structure includes a scattering film and a polarizer which are sequentially laminated on the package substrate along the direction away from the package substrate.

Forming the scattering structure on the package substrate includes: sequentially forming the scattering film and the polarizer on the package substrate.

The scattering film is adhesive, the scattering film may be directly attached to the package substrate, and then the polarizer may be attached to the scattering film.

In another embodiment of the present disclosure, the polarizer and the scattering film may be sequentially laminated on the package substrate along the direction away from the package substrate.

Forming the scattering structure on the package substrate includes: sequentially forming the polarizer and the scattering film on the package substrate.

In another embodiment of the present disclosure, the scattering structure includes a polarizer, an adhesive layer, and a CG. The adhesive layer includes acrylic particles. The polarizer, the adhesive layer, and the CG are sequentially laminated on the package substrate along the direction away from the package substrate.

Forming the scattering structure on the package substrate includes: forming the polarizer on the package substrate; and

bonding the polarizer and the CG by the adhesive layer.

The polarizer is adhesive, and polarizer may be directly attached to the package substrate.

In the embodiments of the present disclosure, the atomized particles include acrylic particles.

Exemplarily, the acrylic particles are doped in the OCR adhesive or OCA; and then the OCR adhesive or OCA is coated on the polarizer; then the OCR adhesive or OCA is covered with the CG; the OCR adhesive or OCA is cured to form the adhesive layer which bonds the polarizer and the CG.

In another embodiment of the present disclosure, the scattering structure includes a transparent insulating layer with an embossing structure configured to change a transmission direction and/or a scattering direction of light and a polarizer. The transparent insulating layer and the polarizer are sequentially laminated on the package substrate along a direction away from the package substrate, and the embossing structure is disposed on a side, facing towards the polarizer, of the transparent insulating layer.

Forming the scattering structure on the package substrate includes: forming the transparent insulating layer on the package substrate.

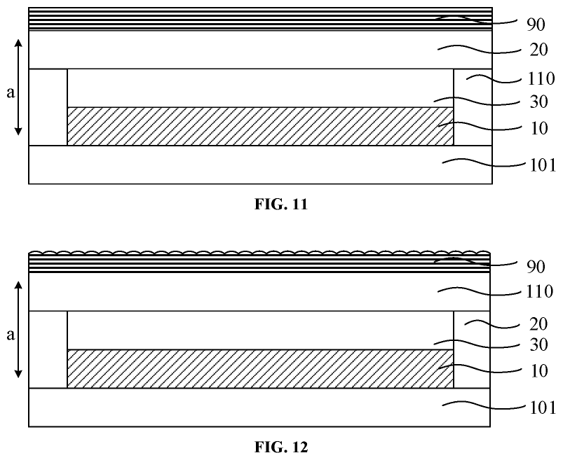

FIGS. 11 to 12 are the process diagrams for manufacturing a scattering structure according to the embodiments of the present disclosure. Referring to FIG. 11, a transparent insulating layer 90 is coated on the package substrate 20. Exemplarily, the transparent insulating layer 90 may be an acrylic film or a polyimide film.

The transparent insulating layer is patterned such that the embossing structure configured to change the transmission direction and/or the scattering direction of light is formed on the surface, distal from the package substrate, of the transparent insulating layer.

Referring to FIG. 12, transparent insulating layer is patterned.

For example, upon coating of the transparent insulating layer 90, the transparent insulating layer 90 is then exposed by using a HTM such that the transparent insulating layer 90 forms an exposure region and a non-exposure region. Subsequently, the transparent insulating layer 90 of the exposure region is removed and the transparent insulating layer 90 of the non-exposure region is retained by using a development process, such that the transparent insulating layer 90 forms an embossing structure on the side towards the polarizer.

In the embodiments of the present disclosure, during the patterning process, different shaped embossing structures may be obtained by controlling the exposure speed and changing the shapes of the HTM.

The polarizer is formed on the side, distal from the package substrate, of the transparent insulating layer.

The scattering structure is formed by attaching the polarizer to the transparent insulating layer.

The embodiments of the present disclosure also provide a display device, and the display device includes the OLED display panel shown in any of the above figures.

In specific embodiments, the display device according to the embodiments of the present disclosure may be any product or component having a display function, such as a mobile phone, a tablet computer, a television, a display, a notebook computer, a digital photo frame, a navigator or the like.

Described above are merely optional embodiments of the present disclosure, and are not intended to limit the present disclosure. Any modifications, equivalent substitutions, improvements, and the like may be made within the protection scope of the present disclosure, without departing from the spirit and principle of the present disclosure.

What is claimed is:

1. An OLED display panel, comprising:
an OLED display substrate;
a package substrate, opposite to the OLED display substrate, wherein a gap is defined between the package substrate and the OLED display substrate, and the gap is filled with a gas having a refractive index less than that of the package substrate; and
a scattering structure, disposed on a side, distal from the OLED display substrate, of the package substrate, wherein the scattering structure is a single-layer or multi-layer structure configured to scatter light passing through the scattering structure.

2. The OLED display panel according to claim 1, wherein the scattering structure is a polarizer with at least one rough surface, wherein the polarizer is disposed on a side, distal from the OLED display substrate, of the package substrate.

3. The OLED display panel according to claim 1, wherein the scattering structure comprises an anti-glare (AG) film and a polarizer which are sequentially laminated on the package substrate along a direction away from the package substrate.

4. The OLED display panel according to claim 1, wherein the scattering structure comprises a scattering film and a polarizer; wherein
the scattering film and the polarizer are sequentially laminated on the package substrate along a direction away from the package substrate.

5. The OLED display panel according to claim 4, wherein the scattering film comprises an internal refractive-index distribution structure configured to control the transmission direction and/or the scattering direction of light.

6. The OLED display panel according to claim 1, wherein the scattering structure comprises a polarizer, an adhesive layer, and a cover glass (CG); wherein
the adhesive layer comprises atomized particles, and
the polarizer, the adhesive layer, and the CG are sequentially laminated on the package substrate along a direction away from the package substrate.

7. The OLED display panel according to claim 6, wherein the atomized particles comprise acrylic particles.

8. The OLED display panel according to claim 1, wherein the scattering structure comprises a transparent insulating layer with an embossing structure configured to change a transmission direction and/or a scattering direction of light and a polarizer;
wherein the transparent insulating layer and the polarizer are sequentially laminated on the package substrate along a direction away from the package substrate, and the embossing structure is disposed on a side, facing towards the polarizer, of the transparent insulating layer.

9. The OLED display panel according to claim 8, wherein the transparent insulating layer is an acrylic layer or a polyimide layer.

10. The OLED display panel according to claim 1, wherein a haze of a layer in which the scattering structure is disposed is between 10% and 90%.

11. The OLED display panel according to claim 1, wherein the gas is nitrogen or an inert gas.

12. The OLED display panel according to claim 1, wherein a base substrate of the OLED display substrate is a rigid substrate, and the package substrate is a rigid substrate.

13. A method for manufacturing an OLED display panel, comprising:
providing an OLED display substrate;
packaging the OLED display substrate by using a package substrate, wherein a gap is defined between the package substrate and the OLED display substrate, the gap being filled with gas having a refractive index less than that of the package substrate; and
forming a scattering structure on the package substrate, wherein the scattering structure is a single-layer or multi-layer structure configured to scatter light passing through the scattering structure.

14. The method according to claim 13, wherein forming the scattering structure on the package substrate comprises:
surface treating the polarizer such that at least one surface of the polarizer is a rough surface; and
attaching the polarizer to a side, distal from the OLED display substrate, of the package substrate.

15. The method according to claim 13, wherein forming the scattering structure on the package substrate comprises:
sequentially forming an AG film and a polarizer on the package substrate.

16. The method according to claim 13, wherein forming the scattering structure on the package substrate comprises:
sequentially forming a scattering film and a polarizer on the package substrate; or
sequentially forming a polarizer and a scattering film on the package substrate.

17. The method according to claim 13, wherein forming the scattering structure on the package substrate comprises:
forming a polarizer on the package substrate; and
bonding the polarizer and a CG by an adhesive layer comprising atomized particles.

18. The method according to claim 13, wherein forming the scattering structure on the package substrate comprises:
forming a transparent insulating layer on the package substrate;
patterning the transparent insulating layer such that an embossing structure configured to change a transmission direction and/or a scattering direction of light is formed on the side, distal from the package substrate, of the transparent insulating layer; and
forming a polarizer on a side, distal from the package substrate, of the transparent insulating layer.

19. A display device, comprising: the an OLED display panel, wherein the OLED display panel comprises:
an OLED display substrate;
a package substrate, opposite to the OLED display substrate, wherein a gap is defined between the package substrate and the OLED display substrate, and the gap is filled with a gas having a refractive index less than that of the package substrate; and
a scattering structure, disposed on a side, distal from the OLED display substrate, of the package substrate, wherein the scattering structure is a single-layer or multi-layer structure configured to scatter light passing through the scattering structure.

20. The OLED display panel according to claim 1, wherein the scattering structure comprises a scattering film and a polarizer; wherein
the polarizer and the scattering film are sequentially laminated on the package substrate along a direction away from the package substrate
